(19) United States
(12) Patent Application Publication
(10) Pub. No.: US 2008/0056855 A1
(43) Pub. Date: Mar. 6, 2008

(54) Vertical diffusion furnace having wafer mapping equipment and method of using the same

(76) Inventor: Sung-Sik Heo, Yongin-si (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/654,001

(22) Filed: Jan. 17, 2007

(30) Foreign Application Priority Data
Aug. 30, 2006 (KR) 2006-0083039

(51) Int. Cl. H01L 21/677

(52) U.S. Cl. 414/217

(57) ABSTRACT

A vertical diffusion furnace for use in fabricating a semiconductor device has a reaction chamber, a wafer boat for supporting wafers, an elevator for moving the boat into and out of the reaction chamber, a transfer device for loading/unloading wafers into/out of the boat, and wafer mapping equipment including a sensor for mapping the wafers in the boat. The wafers are mapped after the transfer device loads the wafers into the boat. The wafer map (constituted by signals generated by the sensor) is compared with stored wafer information. A processing error is revealed when the wafer information does not correspond to the wafer map. On the other hand, the boat is moved into the reaction chamber when the wafer information corresponds to the wafer map. The wafers are mapped again after the wafers have been processed and the boat is lowered out of the reaction chamber. This time, the wafer map can be used to check whether any of the wafers have been damaged during processing.

### BACKGROUND OF THE INVENTION

1. Field of the Invention

The present invention relates to a vertical processing apparatus such as a vertical diffusion furnace for use in fabricating semiconductor devices and to a method of operating such an apparatus. More particularly, the present invention relates to wafer mapping equipment for mapping wafers in a boat of a vertical processing apparatus and to a method of using the same during the processing of wafers by the apparatus.

2. Description of the Related Art

In general, a semiconductor device is fabricated by subjecting a wafer to many different fabrication processes including a chemical vapor deposition (CVD) process or a diffusion process. A chemical vapor deposition (CVD) process or a diffusion process is used to form a poly-silicon layer, a nitride layer, an oxide layer and the like, on the wafer.

A CVD or diffusion process can be classified as a single type or a batch type of process. A vertical diffusion furnace is generally used to carry out the batch-type of process. The vertical diffusion furnace includes a reaction chamber and a boat for supporting a number of wafers in the reaction chamber. The boat is typically formed of quartz.

Also, the boat includes an upper plate and a lower plate each of which has the shape of a disk, and three or four vertical rods connecting the upper and lower plates to each other. Each rod has a number of horizontal grooves spaced vertically along the length thereof. Each groove in a rod is located at the same level as, i.e., is horizontally aligned with, respective grooves in the other rods. Accordingly, an outer peripheral portion of each wafer is received in a slot constituted by a respective set of horizontally aligned slots. The wafers are thus supported as oriented horizontally and spaced vertically from one another.

The vertical diffusion furnace also includes an elevator for moving the boat up and down into and out of the reaction chamber of the furnace. Thus, a number of wafers to be processed can be simultaneously placed into the reaction chamber. More specifically, the wafers are transferred from a wafer cassette-into the boat by a wafer transfer device. The transfer device is interposed between the boat and the cassette when the boat is disposed outside of (below) the reaction chamber. The transfer device includes a head that can reciprocate linearly between the boat and the cassette. The head has a plurality of forks which simultaneously transfer a number of wafers from the cassette to the boat. The boat is raised by the elevator up into the reaction chamber after a predetermined number of wafers have been loaded into the boat by the forks of the transfer device.

The inside of the reaction chamber is completely sealed from the outside environment after the boat has been raised into the reaction chamber. At this time, a vacuum and a high temperature are established in the reaction chamber. Then, a processing gas is injected into the reaction chamber to process the wafers. Once the process has been completed, the boat is moved downwardly out of the reaction chamber. Then, the processed wafers are transferred by the transfer device from the boat to the wafer cassette.

However, a rapid change in temperature may occur immediately after the process in the reaction chamber has been completed. Such a rapid temperature change may, in turn, cause a wafer to break. Moreover, parts of the broken wafer may hang downwardly in the boat In this case, the forks of the transfer device collide with part(s) of the wafer during the operation in which the processed wafers are being transferred from the boat to the wafer cassette. As a result, the boat can be knocked down or the forks can be broken. Also, small pieces of the broken wafer may fall onto the surface of the wafer located directly under the broken wafer in the boat, thereby contaminating the unbroken wafer. Still further, pieces of the broken wafer may remain in the boat after all of the processed wafers have been transferred to the wafer cassette. In this case, the next batch of wafers to be processed may be placed on or collide with the pieces of the broken wafer remaining in the boat. This causes a very serious processing error.

### SUMMARY OF THE INVENTION

Therefore, one object of the present invention is to enhance the efficiency and productivity of a vertical wafer processing apparatus such as a vertical diffusion furnace.

A more specific object of the present invention is to prevent damaged wafers from creating further damage and/or processing errors in a vertical wafer processing apparatus such as a vertical diffusion furnace.

According to one aspect of the present invention, there is provided a vertical diffusion furnace or the like which can accurately map wafers loaded into a boat before the boat is loaded into a reaction chamber of the furnace and/or immediately after the wafers in the boat have been processed in the reaction chamber. The furnace has an elevator for moving the boat into and out of the reaction chamber, a transfer device for loading/unloading wafers into/out of the boat, and wafer mapping equipment including a sensor for mapping the wafers in the boat. Preferably, the wafer mapping sensor is a photo sensor and more preferably, an array of light emitters and light receptors.

According to another aspect of the present invention, there is provided a method of operation of a vertical processing apparatus for processing wafers, which includes mapping the wafers in the boat of the apparatus after the wafers have been loaded into the boat and before the wafers are processed. First, the wafers are removed from a cassette. Subsequently, the wafers are loaded into the boat. The wafers are then mapped. Stored wafer information, i.e., a stored wafer map, is then compared with the generated wafer map, and a determination is made as to whether the stored wafer information corresponds to the wafer map. A signal representing a processing error is generated when the wafer information does not correspond to the wafer map. On the other hand, the boat is raised into a reaction chamber when the wafer information corresponds to the wafer map.

According to still another aspect of the present invention, there is provided a method of operation of a vertical processing apparatus for processing wafers, which includes mapping the wafers in the boat of the apparatus after the wafers have been processed in a boat in the reaction chamber of the apparatus and before the wafers are unloaded from the boat. First, the wafers are removed from a cassette. Subsequently, the wafers are loaded into the boat, the boat is raised into the reaction chamber, and the wafers in the boat are processed in the reaction chamber. The boat is lowered out of the reaction chamber once the wafers have been processed. The processed wafers in the boat are then mapped to thereby generating a wafer map. Stored wafer information is compared with the wafer map, and a determination is made as to whether the wafer information corresponds to the wafer map. A signal representing a processing error is generated when the wafer information does not correspond to the wafer map. On the other hand, the wafers are removed from the boat when the stored wafer information corresponds to the second wafer map.

### BRIEF DESCRIPTION OF THE DRAWINGS

The above and other objects features and advantages of the present invention will become more apparent to those of ordinary skill in the art by referring to the following detailed description of the preferred embodiments thereof made with reference to the attached drawings in which:

FIG. 1 is a schematic perspective view of a vertical processing apparatus (diffusion furnace) for use in fabricating a semiconductor device, according to the present invention;

FIG. 2 is a side view, partially in section, of the vertical processing apparatus of FIG. 1;

FIG. 3 is a schematic side view of a wafer transfer device and wafer mapping equipment according to of the present invention;

FIG. 4 is a front view of a wafer mapping sensor of the wafer mapping equipment according to the present invention;

FIGS. 5A and 5B are flow charts illustrating a method of operating a vertical processing apparatus using a wafer mapping process according to the present invention; and

FIG. 6 is a side view of a section of the processing apparatus and illustrates how the wafer mapping process is performed according to the present invention.

### DETAILED DESCRIPTION OF THE PREFERRED EMBODIMENTS

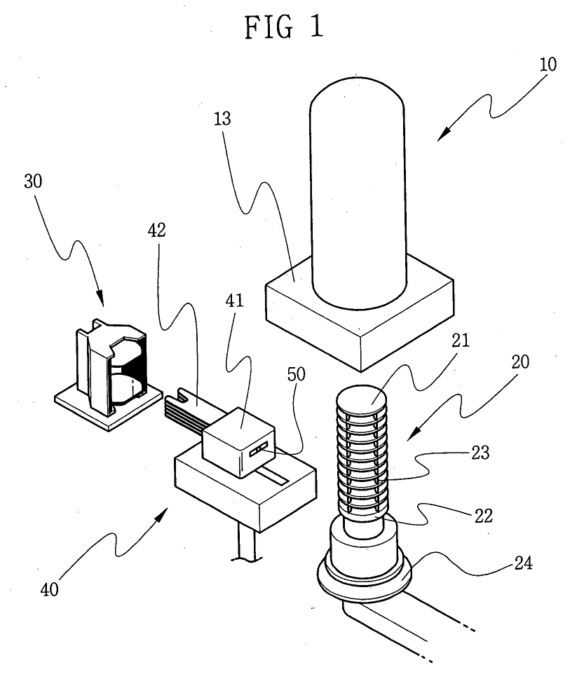

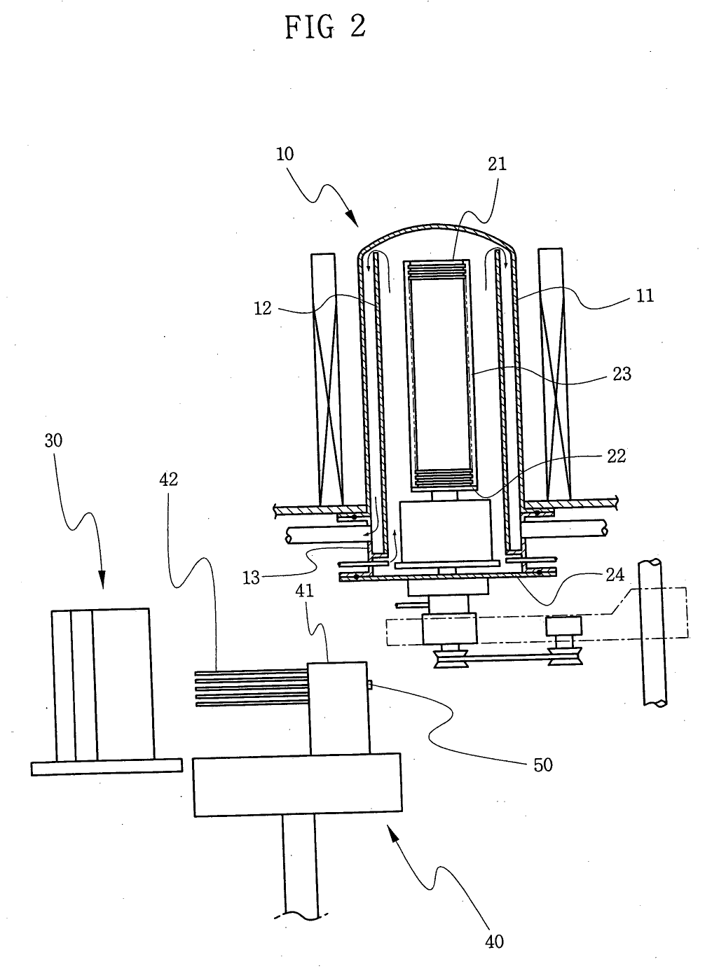

Referring first to FIGS. 1 and 2, a vertical processing (e.g., annealing) apparatus for use in fabricating a semiconductor device according to the present invention includes a reaction chamber 10, a manifold 13, a boat 20, a cassette 30, a substrate (wafer) transfer device 40, and wafer mapping equipment including a wafer mapping sensor 50. A heater (not shown) is provided outside the reaction chamber 10, and the reaction chamber 10 is connected to an upper part of the manifold 13.

More specifically, the reaction chamber 10 has a double-walled structure including a tubular outer wall 11 and a tubular inner tubular 12. The tubular outer wall 11 has a closed top and an open bottom. The diameter of the tubular inner wall 12 is smaller than that of the tubular outer wall 11 and is open at both the top and bottom thereof. The manifold 13 is also open at both the top and bottom thereof. The manifold 13 includes a main wall and a flange that extends radially inwardly from the main wall. The bottom of the tubular outer wall 11 of the reaction chamber 10 is connected to the upper part of main wall of the manifold 13. The bottom of the tubular inner wall 12 is connected to the inwardly extending flange of the manifold 13. The tubular outer wall 11 and the tubular inner wall 12 are concentric such that an annular space is defined between their opposing inner and outer circumferential surfaces. A reaction space in which the wafers are processed is defined inside the tubular inner wall 12. On the other hand, reaction gas (by-products of the process or non-reacted gas) is exhausted from the reaction chamber 10 through the space defined between the tubular outer tubular 11 and the tubular inner wall 12.

An elevator (dashed lines in FIG. 2) disposed under the reaction chamber 10 moves the boat 20 up or down into or out of the reaction chamber 10 through the manifold 13. The boat 20 is generally formed of quartz. A cover 24 is provided at a lower end of the boat 20. The cover 24 is secured against the bottom of the manifold 13 so as to close the reaction chamber 10 when the elevator raises the boat 20 into the reaction chamber 20.

The boat 20 includes an upper plate 21 and a lower plate 22 each having the shape of a disk, and three or four rods 23 extending between and connecting the upper plate 21 and the lower plate 22.

Each rod 23 has a number of horizontal grooves, e.g., one hundred grooves, spaced vertically along the length thereof. Each groove in a rod 23 is located at the same level as, i.e., is horizontally aligned with, respective grooves in the other rods 23. Accordingly, an outer peripheral portion of each wafer is received in a slot constituted by a respective set of horizontally aligned grooves 23. The width of each slot is greater than the thickness of a wafer. The wafers are thus supported by the rods 23 as oriented horizontally and spaced vertically from one another.

A wafer cassette 30 supports a “lot” of wafers. Several of the wafer cassettes are movable between various loading/unloading stations of processing equipment while each supporting a “lot” of wafers. In the present embodiment, the “lot” consists of twenty-five wafers. Therefore, four to five lots of wafers are loaded into the boat 20 from respective ones of the wafer cassettes 30 before the boat 20 is raised up into the reaction chamber 10. In this respect, the furnace includes a loading/unloading station (see FIG. 1) configured to support a cassette 30.

The transfer device 40 transfers wafers between the boat 20 and a cassette 30 disposed at the loading/unloading station of the vertical processing apparatus. The transfer device 40 includes a transfer head 41 disposed at an upper part of the device. The transfer head 41 is supported so as to be movable up and down, rotatable about a vertical axis, and linearly movable horizontally. The transfer device 40 also includes one to five forks 42 attached to one side of the head 41. Each of the forks 42 is configured to support a wafer and thus, the transfer device 40 can transfer one to five wafers W at a time.

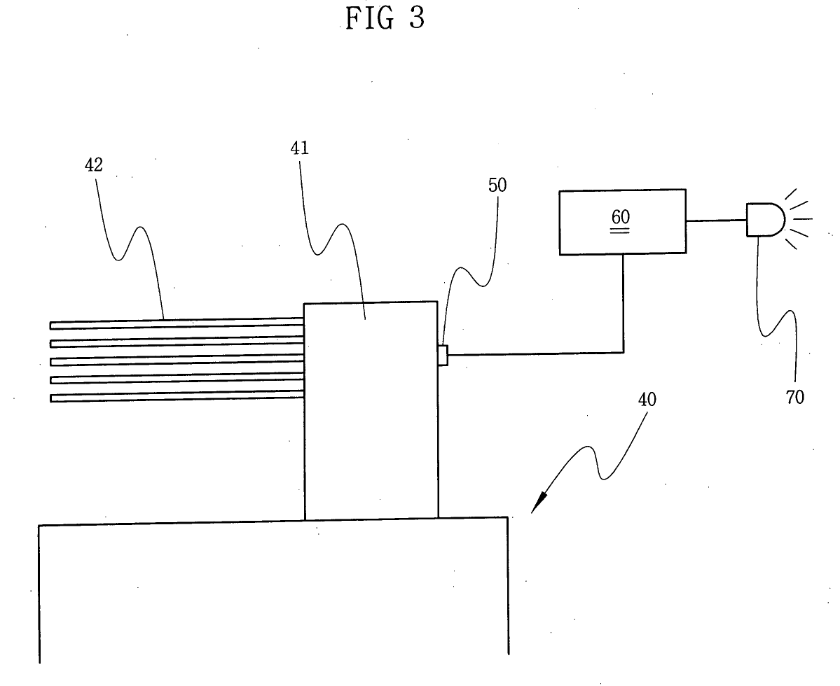

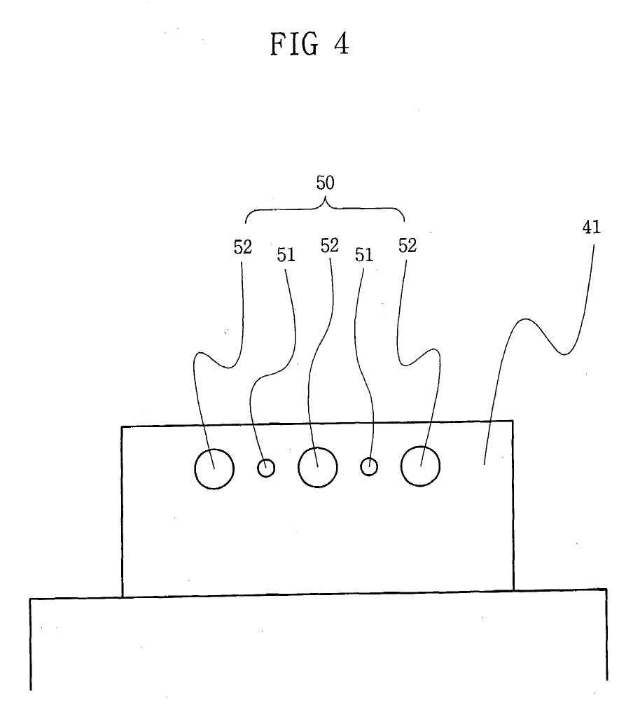

Referring now to FIG. 3, a wafer mapping sensor 50 is disposed on the transfer head 41 of the wafer transfer device 40, and preferably on the side of the head 41 opposite that from which the forks 42 extend. The wafer mapping sensor 50 may be a photo sensor array. More specifically, as shown in FIG. 4, the wafer mapping sensor 50 preferably includes a plurality of light receptors 51 and a plurality of light emitters 52. The light receptors 51 and the light emitters 52 may be alternately disposed across the head 41. The wafer mapping sensor 50 can be positioned close to the boat 20 and is operative to sense whether a wafer is present in each slot of the boat 20. In particular, the wafer mapping sensor 50 maps the wafers in the boat 20 while being moved up and down by the wafer transfer device 40.

To this end, light is emitted by the light emitters 52 each time the wafer mapping sensor 50 is positioned across from a slot of the boat 20. If a wafer is present in the slot, the light is reflected back by the wafer to the light emitters 52. The quantity of the reflected light received by the light emitters 52 is converted to signals that indicate whether a wafer is present in the slot. Also, the photo sensor array spans the slot so that the quantity of the reflected light received by the light emitters 52 can also indicate whether a wafer in the slot is whole, i.e., whether a piece(s) of the wafer has/have broken off and has/have fallen from the slot.

The vertical processing apparatus also includes a controller 60 (FIG. 3) for controlling the operation of the apparatus. The controller 60 is operatively connected to the wafer mapping sensor 50 to receive signals therefrom representative of the wafers in the slots of the boat 20. The controller 60 controls the operation of the vertical processing apparatus based on the signals generated by the wafer mapping sensor 50. In addition, the apparatus may include an alarm 70, such as a buzzer or a lamp, operatively connected to the controller 60. The controller 60 triggers the alarm 70 and immediately stops the operation of the apparatus when signals from the wafer mapping sensor 50 indicate that a complete wafer is not present in one of the designated slots of the boat 20, whereupon an engineer can immediately take the necessary action.

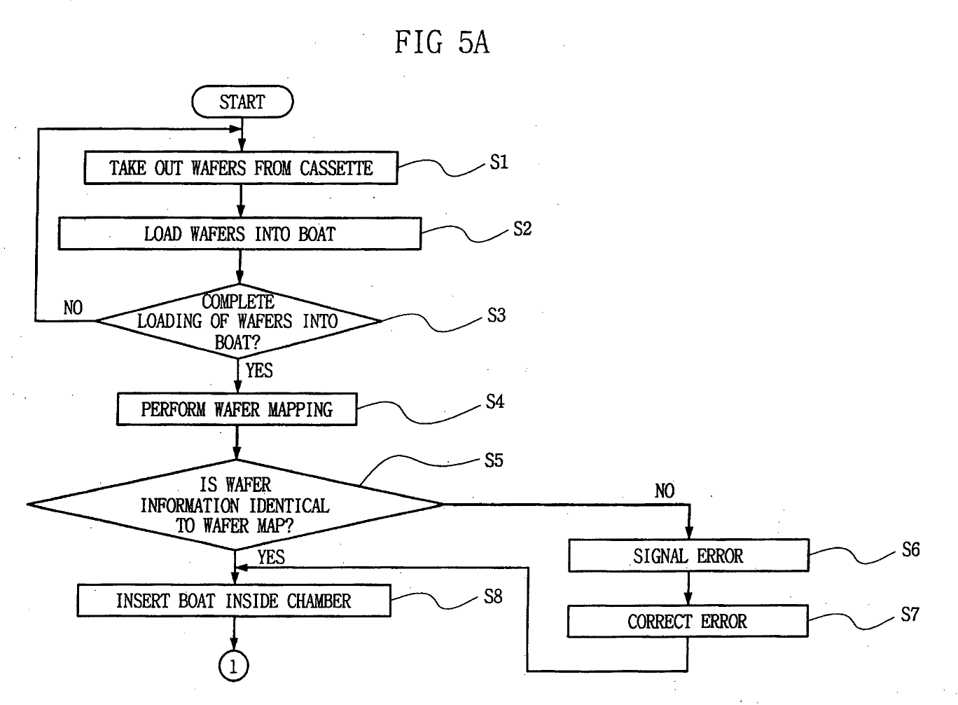

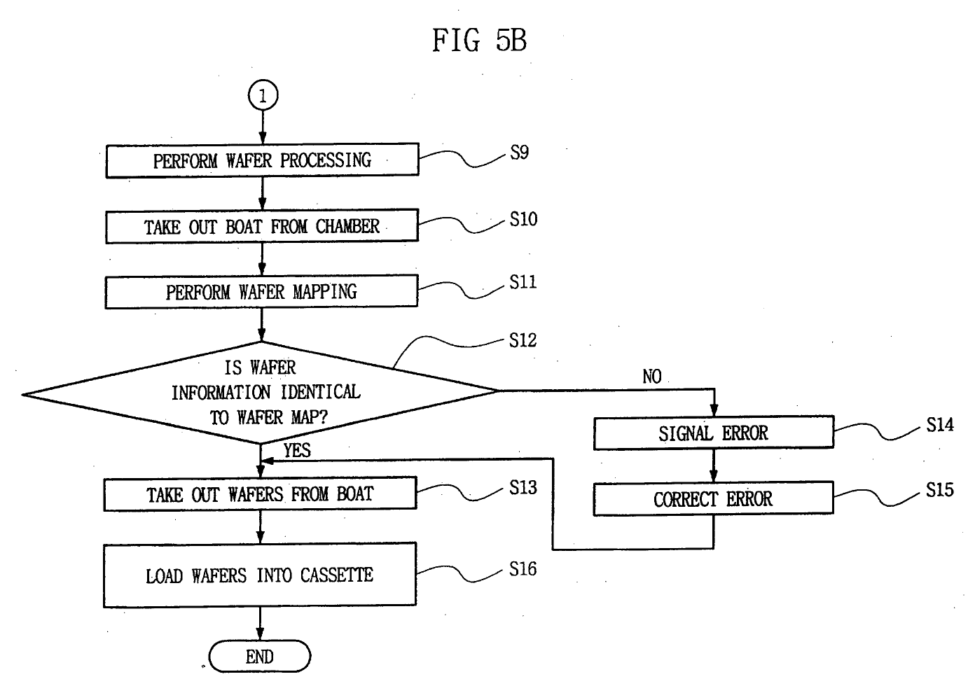

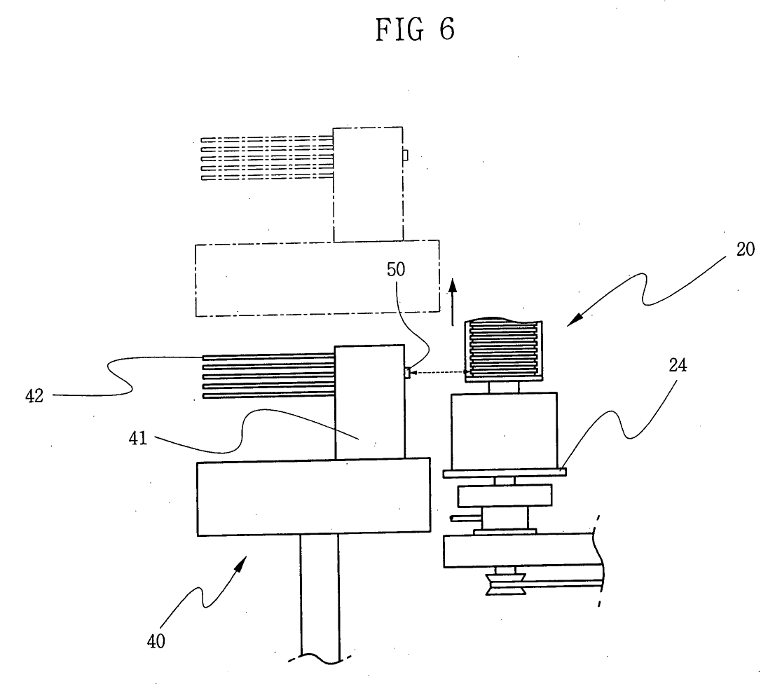

A method of processing wafers using the processing apparatus having the wafer mapping sensor will now be described with reference FIGS. 5A, 5B and 6.

First, a number of wafers are transferred by the wafer transfer device 40 from one or more wafer cassettes 30 into the boat 20 (S1). In this respect, a lot of wafers is removed from a cassette, supported at the wafer loading/unloading station of the apparatus, by moving the transfer head 41 linearly toward the cassette so that the forks 42 are inserted into the cassette between the wafers inside the cassette. Then, the forks 42 are raised a predetermined amount so that the wafers are respectively supported by the forks 42. In this state, the transfer head 41 is retracted to withdraw the wafers from the cassette.

Secondly, the wafers are loaded into the boat 20 (S2). Specifically, the transfer head 41 is rotated so that the forks 42 supporting the wafers face the boat 20. The transfer head 41 is then moved linearly so that the wafers W are inserted into the slots of the boat 20. Then, the transfer head 41 is lowered a predetermined amount so that the wafers come to rest on the boat 20 at the bottom the slots of the boat 20, respectively. At this time, the upper surfaces of the forks 42 separate from the wafers, respectively. Finally, the head 41 is moved backward away from the boat 20 so that the forks 42 are withdrawn from the boat 20 and then the head 41 is again rotated so that the forks 42 face the cassette station.

These operations are repeated until slots of the boat 20 are filled with the wafers W (S3). Foe example, four to five lots of wafers are loaded into the boat 20. Once the boat 20 has been filled, the head 41 of the wafer transfer device 40 is rotated such that the wafer mapping sensor 50 faces the boat 20. Then, a wafer mapping process is performed (S4). FIG. 6 is a side view of the processing apparatus illustrating a wafer mapping process performed according to the present invention.

In this process, the wafer mapping sensor 50 is moved vertically by the wafer transfer device 40 by increments stored in the controller 60. The increments correspond to the distances between the slots of the boat 20. Thus, the wafer mapping sensor 50 is positioned in front of each slot of the boat. Each time the wafer mapping sensor 50 is positioned in front of a slot, the sensor 50 checks the slot and issues signals to the controller 60 representing the state of a wafer in the slot. As explained previously, the signals can indicate whether a wafer is present in the slot. The signals thus provide a map of the wafers in the boat 20.

Information pertaining to the wafers is stored in the controller 60. The wafer information thus includes the positions that the wafers are to assume in the boat 20. The map of the wafers is checked against this information to determine whether the wafers have been accurately transferred to the boat 20. That is, a determination is made as to whether the wafer information is identical to the wafer map (S5). An error is determined to have occurred when the wafer information is different from the wafer map after the wafers have been loaded into the boat 20, i.e., when a wafer is not present in a specific slot of the boat 20 (S6). Simultaneously, the controller 60 shuts down the apparatus, and triggers the alarm 70. An engineer senses the alarm and acts on the alarm to correct the error (S7).

On the other hand, the boat 20 is raised by the elevator into the reaction chamber 10 when the wafer information is identical to the wafer map or once any error has been corrected (S8). At this time, the cover 24 at the lower end of the boat 20 is secured against the bottom of the manifold 13 to seal the reaction chamber 10. Subsequently, a specific processing environment is formed in the reaction chamber 10 and the wafers are processed (S9). After the wafers have been processed, the boat 20 is lowered by the elevator out of the reaction chamber 10 (S10).

The wafer mapping sensor 50 is again positioned close to the boat 20 and starts mapping the wafers (S11). The wafer mapping process is performed in the same manner as that before the wafers have been processed, i.e., by moving the wafer mapping sensor 50 in predetermined increments in front of the boat 20. This time, though, the wafer mapping process is used to check whether there have been any changes in the disposition of the wafers in the boat 20 between the time the wafers have been loaded in the boat 20 and the time the processing of the wafers has been completed.

The processed wafers are taken out of the boat 20 by the wafer transfer device 40 when the wafer information is identical to the wafer map (S13). However, an error is determined to have occurred when the wafer information is different from the wafer map after the boat 20 has been removed from the reaction chamber (S14). Simultaneously, the controller 60 shuts down the apparatus, and triggers the alarm 70. An engineer senses the alarm and acts on the alarm to correct the error (S15). In this case, though, the error may be the result of the wafers having become broken or damaged due to various reasons such as a sudden change in temperature inside the reaction chamber during the processing of the wafers. For instance, the wafer map will indicate no wafer present in the slot of the boat when a wafer is totally destroyed during processing. In addition, the wafer map will indicate irregularities even when a wafer is only broken during processing because a broken portion of the wafer will hang down from the slot.

Accordingly, an error indicated as a result of the wafer mapping process is corrected by removing a damaged wafer and its residue from the boat 20. The disposition of the wafers in the boat 20 is changed once a damaged wafer has been removed. This change may be manually input to the controller to generate new wafer information. Alternatively, the wafer mapping process can be performed again and the wafer information can be replaced (updated) with the new wafer map produced as a result of this process.

The wafers removed from the boat 20 are appropriately loaded into cassettes 30 (S13). However, an error in the unloading process may cause a wafer or a broken portion of a wafer to remain in the boat 20. Therefore, the wafer mapping process is performed after the boat 20 has been unloaded and the processed wafers have been transferred into the cassettes 30 (or just before the next lot of wafers to be processed is loaded into the boat from a cassette 30). This will prevent the next batch of wafers to be processed from being damaged when they are loaded into the boat.

As described above, the present invention is capable of periodically mapping the wafers in the boat 20. For instance, the wafer mapping sensor 50 is used to check the boat 20 after the wafers have been loaded into the boat 20. Thus, the present invention checks the wafer transfer process and can determine whether any of the wafers have been damaged by the transfer process. Any damaged wafers can be immediately removed from the boat and the wafer transfer device can be recalibrated, if necessary.

The wafer mapping sensor 50 can also be used to check the boat 20 after the wafers have been processed. Therefore, the present invention can determine whether any of the wafers have been broken or damaged while the wafers were being processed. Thus, any damaged wafers or broken pieces thereof can be removed once the boat 20 has been moved out of the reaction chamber 10. Otherwise, a broken wafer could fall from the forks 42 of the transfer device 40 onto the upper surface of an underlying wafer in the boat 20 as the broken wafer is being unloaded from the boat 20. A broken wafer could also fall from the forks 42 once the wafer was removed from the boat 20. Also, new wafers to be processed could be placed on or collide with a piece of a wafer remaining in the boat 20. Likewise, the forks 42 of the transfer device 40 could collide with a piece of a wafer remaining in the boat 20 and thereby damage the boat 20. However, the present invention ensures that broken or damaged wafers are removed from the boat 20 before they create any of these problems. Consequently, the present invention enhances the overall efficiency of the processing of the wafers, the productivity of the process, and the reliability of the products produced by the process.

Finally, although the present invention has been described in connection with the preferred embodiments thereof, it is to be understood that the scope of the present invention is not so limited. On the contrary, various modifications of and changes to the preferred embodiments will be apparent to those of ordinary skill in the art. Thus, changes to and modifications of the preferred embodiments may fall within the true spirit and scope of the invention as defined by the appended claims.

What is claimed is:

1. A vertical processing apparatus comprising:
a reaction chamber in which a space for processing wafers is defined;
a boat configured to support a plurality of wafers as spaced vertically from one another;
an elevator connected to the boat and operative to move the boat up and down between a first position at which the boat is disposed beneath the reaction chamber and a second position at which the boat is disposed within the reaction chamber;
a cassette station configured to support a cassette for accommodating a plurality of wafers;
a transfer device interposed between the cassette station and the boat and operative to transfer wafers between the boat and a cassette when the boat is at the first position thereof and the cassette is supported by the cassette station;
a mapping sensor supported so as to be movable vertically adjacent the boat when the boat is at the first position thereof, the mapping sensor operative to generate signals that represent a map of the wafers in the boat; and
a controller operatively connected to the mapping sensor to receive the signals from the mapping sensor.

2. The apparatus according to claim 1, wherein the transfer device includes a transfer head that is movable linearly between the cassette station and the boat when the boat is at the first position thereof, and the mapping sensor is disposed on the transfer head.

3. The apparatus according to claim 2, wherein transfer device includes a plurality of forks extending from one side of the transfer head, and the mapping sensor is disposed on a side of the transfer head opposite that from which forks extend.

4. The apparatus according to claim 1, wherein the mapping sensor comprises a photo sensor.

5. The apparatus according to claim 4, wherein the photo sensor includes a plurality of light receptors and a plurality of light emitters.

6. The apparatus according to claim 5, wherein the light receptors and light emitters are alternately disposed across the transfer head in a horizontal direction.

7. The apparatus according to claim 2, wherein the mapping sensor comprises a photo sensor.

8. The apparatus according to claim 7, wherein the photo sensor includes a plurality of the light receptors and a plurality of light emitters.

9. The apparatus according to claim 8, wherein the light receptors and light emitters are alternately disposed across the transfer head in a horizontal direction.

10. The apparatus according to claim 1, and further comprising an alarm operatively connected to the controller.

11. A method of operation of a vertical processing apparatus for processing wafers, comprising:
removing wafers from a cassette;
subsequently loading the wafers into a boat;
mapping the wafers loaded in the boat and thereby generating a wafer map;
comparing stored wafer information with the wafer map, and determining whether the wafer information corresponds to the wafer map;
generating a signal representing a processing error when the wafer information does not correspond to the wafer map;
raising the boat into a reaction chamber when the wafer information corresponds to the wafer map; and
processing the wafers in the boat in the reaction chamber.

12. The method of claim 11, further comprising:
lowering the boat out of the reaction chamber once the wafers have been processed;
subsequently mapping the processed wafers in the boat and thereby generating a second wafer map
comparing stored wafer information with the second wafer map;
generating a signal representing a processing error when the wafer information compared with the second wafer map does not correspond to the second wafer map;
removing the wafers from the boat when the wafer information compared with the second wafer map corresponds to the second wafer map; and
loading wafers removed from the boat into a cassette.

13. The method of claim 12, further comprising:
mapping the boat after wafers have been removed from the boat for loading into the cassette, and thereby generating another wafer map; and
generating a signal representing a processing error when said another wafer map reveals the presence of a wafer or a portion of a wafer in the boat.

14. A method of operation of a vertical processing apparatus for processing wafers, comprising:
removing wafers from a cassette;
subsequently loading the wafers into a boat;
subsequently raising the boat into a reaction chamber;
processing the wafers in the boat in the reaction chamber
lowering the boat out of the reaction chamber once the wafers have been processed;
subsequently mapping the processed wafers in the boat and thereby generating a wafer map
comparing stored wafer information with the wafer map, and determining whether the wafer information corresponds to the wafer map;
generating a signal representing a processing error when the wafer information does not correspond to the wafer map; and
removing the wafers from the boat when the wafer information corresponds to the second wafer map.

15. The method of claim 14, wherein a signal representing a processing error is generated when the wafer map reveals the absence of a wafer from a designated slot of the boat or the presence of only a portion of a wafer in a designated slot of the boat.

16. The method of claim 14, further comprising:
mapping the boat after wafers have been removed from the boat for loading into the cassette, and thereby generating another wafer map; and
generating a signal representing a processing error when said another wafer map reveals the presence of a wafer or a portion of a wafer in the boat.
